(19) United States
(12) Patent Application Publication
(10) Pub. No.: US 2008/0068109 A1
(43) Pub. Date: Mar. 20, 2008

(54) TRANSCEIVER CIRCUIT

(76) Inventor: Edgar Schmidhammer, Stein (DE)

Correspondence Address: FISH & RICHARDSON PC, P.O. BOX 1022, MINNEAPOLIS, MN, 55440-1022, US

(21) Appl. No.: 11/773,738

(22) Filed: Jul. 5, 2007

(30) Foreign Application Priority Data
Jul. 7, 2006 (DE) 10 2006 031 548.0

(51) Int. Cl. H03H 9/70

(52) U.S. Cl. 333/133

(57) ABSTRACT

A transceiver circuit includes a duplexer having a transmit band for transmit signals and a receive band for receive signals, and an antenna circuit electrically connected to the duplexer. The antenna circuit is configured to generate at least one stop band in a frequency range in which noise signals are received. An intermodulation product of the noise signals and the transmit signals is in the receive band of the transceiver circuit.

### CLAIM TO PRIORITY

This patent application claims priority to German patent application no. 102006031548.0, which was filed on Jul. 7, 2006. The contents of German patent application no. 102006031548.0 are hereby incorporated by reference into this patent application as if set forth herein in full.

### BACKGROUND

A transceiver circuit containing a duplexer is described in U.S. patent publication no. 2004/0119562 A1.

### SUMMARY

Described herein is a transceiver circuit that suppresses noise signals.

The transceiver circuit includes a duplexer with a transmission band for transmitting signals, a receiving band for receiving signals, and an antenna circuit connected to the duplexer. The antenna circuit generates at least one stop band in a frequency range in which signals to be suppressed are received. An intermodulation product of the received signals to be suppressed and the transmit signals is in the receiving band of the transceiver circuit.

The duplexer comprises a transmit filter and a receive filter. Both filters are connected on an antenna side to a common antenna path. The transmit filter is between the antenna path and a transmit path, where the transmit path includes a transmit generator and an amplifier. The receive filter is between the antenna path and a receive path, where the receive path includes a preamplifier and a receiver.

Noise signals received on the antenna side are damped in the antenna circuit before the noise signals arrive at the intersection point of the transmit and receive paths. As a result, a level of the intermodulation signals is reduced.

The transceiver circuit dampens the intermodulation signals so that a level of the intermodulation signals in the receive path does not exceed −105 dBm. In another implementation, the transceiver circuit dampens the intermodulation signals so that a level of the intermodulation signals in the receive path does not exceed −110 dBm.

In an embodiment, the antenna circuit has a stop band comprising a frequency that corresponds to a difference between a transmit frequency of the transceiver circuit and a receive frequency of the transceiver circuit. This stop band may be a first stop band.

The antenna circuit can also have a stop band comprising a frequency that corresponds to a sum of a transmit frequency of the transceiver circuit and a receive frequency of the transceiver circuit. This stop band may be a second stop band.

In an embodiment, the antenna circuit has only the first stop band and in another embodiment the antenna circuit has only the second stop band. An embodiment that has both the first stop band and the second stop band is also described herein.

An antenna circuit containing at least two parts with stop ranges that are different from each other may be used if the first stop band and the second stop band are more than an octave apart. A first part of the antenna circuit may include a first bandstop filter. A second part of the antenna circuit may include a second bandstop filter, a high-pass filter, or a low-pass filter.

In an embodiment, the antenna circuit comprises a bandstop filter, which is configured to suppress signals in the first stop band of the antenna circuit. The antenna circuit may also include another bandstop filter, which is configured to suppress signals in the second stop band. Alternatively, the antenna circuit can comprise a low-pass filter having a cutoff frequency that is between the first stop band and the second stop band. The second stop band may be in the stop range of the low-pass filter.

In an embodiment, the antenna circuit comprises a bandstop filter, where the bandstop filter is configured to suppress signals in the second stop band of the antenna circuit. The antenna circuit may include another bandstop filter, which is configured to suppress signals in the first stop band. Alternatively, the antenna circuit can comprise a high-pass filter with a cutoff frequency that is between the first stop band and second stop band. The first stop band may be in the stop range of the high-pass filter.

The bandstop filter can comprise at least one acoustic wave resonator. The bandstop filter can comprise a series resonator and a parallel resonator. These resonators may be elements of a bandstop ladder-type arrangement. The series resonance of the parallel resonator may substantially match the parallel resonance of the series resonator.

The low-pass filter or the high-pass filter of the antenna circuit can also comprise at least one acoustic wave resonator. The acoustic wave resonator has a static capacitance that can be used as a capacitive element in the low-pass filter or in the high-pass filter. The low-pass filter or high-pass filter can also comprise at least one capacitor and one inductor, winch may be integrated into a carrier substrate, as explained below.

The low-pass filter or the high-pass filter can comprise (in an equivalent circuit) at least one L-element, one-T element, or one π-element.

In an embodiment, the bandstop filter can comprise a shunt arm that includes a series circuit comprised of a capacitor and an inductor. These form an acceptor circuit having a resonance frequency that is in the first stop band or the second stop band of the antenna circuit.

In an embodiment, the antenna circuit comprises an antenna configured to guarantee suppression of signals in one of the stop bands of the antenna circuit. In this embodiment, the antenna has a transmission range that does not overlap at least one of the stop bands of the antenna circuit. The first stop band or the second stop band may be in the stop range of the antenna.

The duplexer may include an acoustic wave resonators, or SAW resonators. These resonators can be, e.g., resonators that operate with surface acoustic waves or resonators that operate with bulk acoustic waves, or BAW resonators. SAW stands for Surface Acoustic Wave and BAW stands for Bulk Acoustic Wave. Because BAW resonators are power-compatible to a high degree, the transmit filter can be constructed using BAW resonators and the receive filter can be constructed using SAW resonators.

The duplexer can comprise BAW resonators, which are coupled to one another and arranged one above the other. The duplexer can also comprise at least one SAW resonator, which comprises SAW converters coupled to one another.

The transceiver circuit may be implemented in a component prepared as a compact, e.g., surface-mountable, component. The component comprises a chip that contains the duplexer. The chip can comprise a piezoelectric substrate, e.g., for the use of SAW resonators. The chip can comprise a semiconductor substrate, e.g., for the use of BAW resonators. Silicon may be used as the material for the semiconductor substrate.

The antenna circuit can be implemented in the chip substrate. Alternatively, the antenna circuit can be implemented in a carrier substrate on which the chip is mounted. The carrier substrate may be used to integrate passive circuit elements of the antenna circuit. Passive circuit elements include, e.g., capacitors, inductors, and line sections. If capacitive elements of the antenna circuit are implemented via resonators, they may be integrated into the chip.

An LTCC ceramic may be used as the material for the carrier substrate. LTCC stands for Low Temperature Co-fired Ceramics. Plastics may also be used for the carrier substrate, e.g., a fluorine-containing material, such as FR4 or organic synthetic materials.

Inductive elements of the antenna circuit may be implemented in a housing of the component. For example, a cover may seal to the carrier substrate and cover the chip.

The antenna circuit can be used as ESD protection for the duplexer. ESD stands for Electrostatic Discharge. The antenna circuit can comprise, e.g., an inductor that is connected to ground and that is configured to operate as an ESD protection element.

Embodiments of the transceiver circuit are described below with, reference to the following drawings.

### DESCRIPTION OF THE DRAWINGS

FIG. 1 shows an example of a transceiver circuit with a duplexer and an antenna circuit that is connected to the duplexer and that comprises a bandstop filter and a high-pass filter.

FIG. 2 shows an example of a transceiver circuit with a duplexer and an antenna circuit that is connected to the duplexer and that comprises a bandstop filter and a low-pass filter.

FIG. 3 shows a transfer function of the antenna circuit of FIG. 1.

FIG. 4 shows a multilayer component with a chip on a carrier substrate.

### DETAILED DESCRIPTION

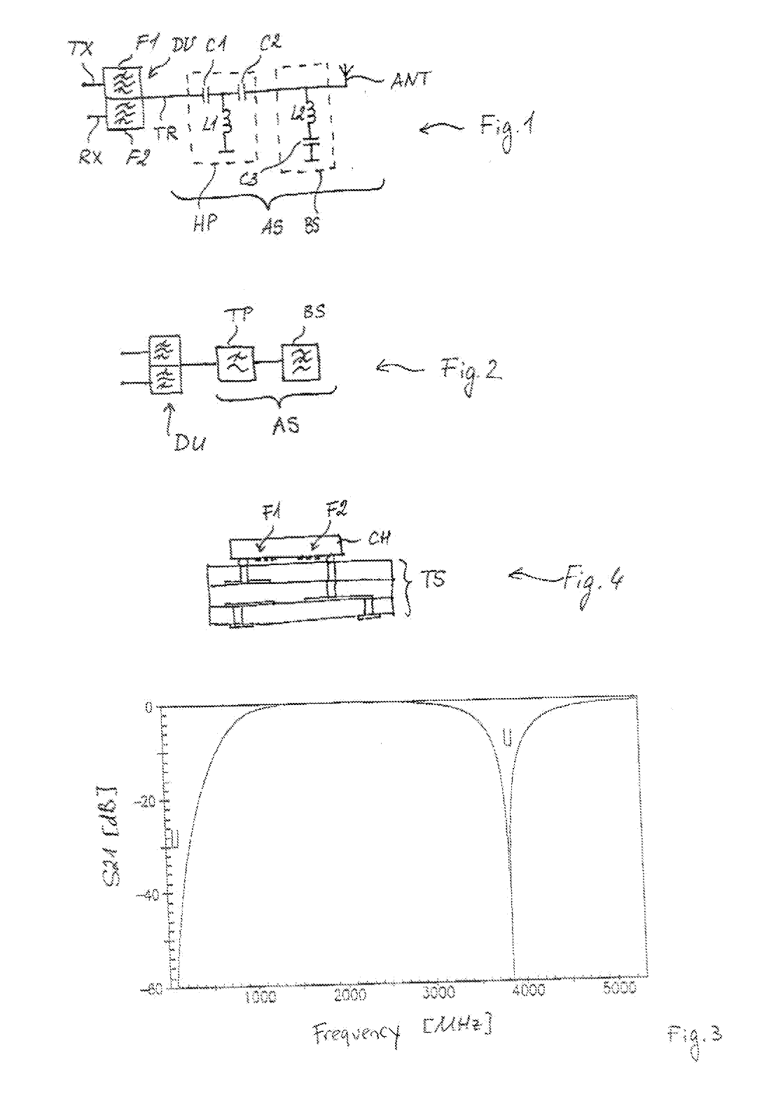

FIG. 1 shows a transceiver circuit that includes a duplexer DU and an antenna circuit AS. The antenna circuit AS is connected to the duplexer DU. The antenna circuit AS comprises a bandstop filter BS and a high-pass filter HP.

The duplexer DU comprises a transmit filter F1 and a receive filter F2. Both filters F1, F2 are connected on a first side of the antenna circuit AS to an antenna path TR that includes the antenna circuit AS. On a second side of the antenna circuit AS, which faces away from the first side, the transmit filter F1 is connected to a transmit path TX and the receive filter F2 is connected to a receive path RX.

The antenna circuit AS comprises a bandstop filter BS and a high-pass filter HP. The bandstop filter BS is configured to suppress noise signals in a second stop band and the high-pass filter is configured to suppress noise signals in a first stop band.

The high-pass filter HP comprises two series capacitors C1, C2 and a parallel inductor L1. The bandstop filter BS comprises a shunt arm to ground that includes an inductor L2 and a capacitor C3. The inductor L2 and the capacitor C3 are connected in series to form an acceptor circuit that generates an HF short circuit to ground at a resonance frequency.

A 0.38 pF capacitor and a 4.5 nH inductor may be used to implement an acceptor circuit having a resonance frequency in the second stop range.

Two 3.9 pP capacitors and a 4.5 nH inductor may be used to implement a high-pass filter comprised of a T-element for suppressing a frequency range of 80 . . . 140 MHz.

The transmit band may be in the frequency range of 1850 . . . 1910 MHz and the receive band may be in the frequency range of 1930 . . . 1990 MHz. These frequency bands correspond to the PCS band. In this configuration, the noise frequencies to be suppressed are in the frequency range of 80 . . . 140 MHz which is in the first stop band, and in the frequency range of 3840 . . . 3900 MHz which is in the second stop band.

The transceiver circuit, however, is not limited to use with the PCS band.

FIG. 2 shows another embodiment of the transceiver circuit, which uses a low-pass filter TP (instead of a high-pass filter) in the antenna circuit AS. In this embodiment, the bandstop filter BS is configured to suppress noise signals in the first stop band and the low-pass filter is configured to suppress noise signals in the second stop band.

The low-pass filter TP can also be replaced by a second bandstop filter, which suppresses signals in the second stop band. The first bandstop filter can be between the duplexer DU and the low-pass filter TP (or the high-pass filter or the second bandstop filter).

FIG. 3 shows a transfer function S21 for the antenna circuit of FIG. 1. The first stop band of the antenna circuit AS is in the frequency range of 80 . . . 140 MHz and the second stop band, i.e., also the resonance frequency of the bandstop filter BS, is in the frequency range of 3840 . . . 3900 MHz.

FIG. 4 shows an example of a component containing the transceiver circuit. The bottom side of the chip CH includes component structures for the transmit filter F1 and the receive filter F2. The chip CH is on a carrier substrate TS and connected electrically to passive circuit elements, which are implemented in the carrier substrate via strip conductor sections and land patterns. For example, capacitors C1, C2, and C3 and inductors L1, L2 may be implemented in the carrier substrate.

The claims are not limited to the embodiments described herein. Different embodiments may be combined to implement new embodiments not specifically described herein.

What is claimed is:

1. A transceiver circuit comprising:
a duplexer having a transmit band for transmit signals and a receive band for receive signals; and
an antenna circuit electrically connected to the duplexer;
wherein the antenna circuit is configured to generate at least one stop band in a frequency range in which noise signals are received, and wherein an intermodulation product of the noise signals and the transmit signals is in the receive band of the transceiver circuit.

2. The transceiver circuit of claim 1, wherein the antenna circuit has a first stop band, the first stop baud corresponding to a difference of a transmit frequency of the transceiver circuit and a receive frequency of the transceiver circuit.

3. Transceiver circuit according to claim 3, wherein the antenna circuit has a second stop band, the second stop band corresponding to a sum of a transmit frequency of the transceiver circuit and a receive frequency of the transceiver circuit.

4. The transceiver circuit of claim 1, wherein the duplexer comprises at least one acoustic wave resonator.

5. The transceiver circuit of claim 3, wherein the antenna circuit comprises:
a bandstop filter configured to suppress signals in the first stop band; and
a low-pass filter having a cutoff frequency that is between the first stop band and the second stop band.

6. The transceiver circuit according to claim 3, wherein the antenna circuit comprises:
a bandstop filter configured to suppress signals in the second stop band; and
a high-pass filter having a cutoff frequency between the first stop band and the second stop band.

7. The transceiver circuit of claim 5, wherein the bandstop filter comprises at least one acoustic wave resonator.

8. The transceiver circuit according to claim 5, wherein the bandstop filter comprises a shunt-arm, the shunt arm comprising series-connected capacitors and inductors.

9. The transceiver circuit of claim 1, wherein the antenna circuit comprises an antenna to suppress signals in a stop band of the antenna circuit.

10. A component comprising;
the transceiver circuit of claim 1; and
a chip comprising the duplexer and the antenna circuit.

11. A component comprising;
the transceiver circuit of claim 1;
a chip comprising the duplexer; and
a carrier substrate on which the chip is arranged;
wherein the antenna circuit comprises capacitors and inductors that are implemented in the carrier substrate.

12. The transceiver circuit of claim 6, wherein the bandstop filter comprises at least one acoustic wave resonator.

13. The transceiver circuit according to claim 6, wherein the bandstop filter comprises a shunt arm, the shunt arm comprising series-connected capacitors and inductors.

14. The transceiver circuit of claim 8, wherein the capacitors and inductors comprise an acceptor circuit configured to generate a short circuit to ground at a resonance frequency.

15. The transceiver circuit of claim 1, wherein the transmit band is in a frequency range of 1850 to 1910 MHz and the receive band is in a frequency range of 1930 to 1990 MHz.

16. The transceiver circuit of claim 1, wherein the transceiver circuit is configured to dampen the intermodulation signals so that a level of the intermodulation signals in a receive path does not exceed −105 dBm.

17. The transceiver circuit of claim 1, wherein the transceiver circuit is configured to dampen the intermodulation signals so that a level of the intermodulation signals in 1 receive path does not exceed −110 dBm.

18. A transceiver circuit comprising:
a duplexer for passing transmit signals and receive signals; and
an antenna circuit electrically connected to the duplexer;
wherein the antenna circuit is configured to generate at least one stop band in a frequency range in which signals to be suppressed are received, and wherein an intermodulation product of the signals to be suppressed and the transmit signals is in a receive band of the transceiver circuit.

19. The transceiver circuit of claim 18, wherein the antenna circuit has a first stop band, the first stop band corresponding to a difference of a transmit frequency of the transceiver circuit and a receive frequency of the transceiver circuit;
wherein the antenna circuit has a second stop band, the second stop band corresponding to a sum of a transmit frequency of the transceiver circuit and a receive frequency of the transceiver circuit; and
wherein the antenna circuit comprises:
a bandstop filter configured to suppress signals in the first stop band of the antenna circuit; and
a low-pass filter having a cutoff frequency that is between the first stop band and the second stop band.

20. The transceiver circuit of claim 18, wherein the antenna circuit has a first stop band, the first stop band corresponding to a difference of a transmit frequency of the transceiver circuit and a receive frequency of the transceiver circuit;
wherein the antenna circuit has a second stop band, the second stop band corresponding to a sum of a transmit frequency of the transceiver circuit and a receive frequency of the transceiver circuit; and
wherein the antenna circuit comprises:
a bandstop filter configured to suppress signals in the second stop band of the antenna circuit: and
a high-pass filter having a cutoff frequency between the first stop band and the second stop band.
